(19) United States
(12) Patent Application Publication
(10) Pub. No.: US 2026/0333894 A1
(43) Pub. Date: Oct. 22, 2026

(54) METHOD FOR MANUFACTURING A PHOTODETECTOR DEVICE AND PHOTODETECTOR DEVICE

(71) Applicant: ams-OSRAM AG, Premstätten (AT)

(72) Inventors: Rainer MINIXHOFER, Premstätten (AT); Bernhard STERING, Stainz (AT)

(21) Appl. No.: 19/486,832

(22) PCT Filed: May 16, 2024
(86) PCT No.: PCT/EP2024/063525

§ 371 Date: Nov. 21, 2025

(30) Foreign Application Priority Data
May 24, 2023 (DE) 10 2023 113 587.2

(51) Int. Cl. H10F 39/10; H10F 77/30

(52) U.S. Cl. CPC H10F 39/107; H10F 77/337

(57) ABSTRACT

A method for manufacturing a photodetector device includes providing a functional wafer with at least two photodetector elements. The photodetector elements are configured to detect electromagnetic radiation of a first wavelength range. The method also includes providing a dielectric wafer that is transmissive for the electromagnetic radiation of the first wavelength range. The dielectric wafer includes at least two recesses and/or at least two penetrations the recesses having bottom faces and the penetrations penetrate the dielectric wafer-completely. The method further includes connecting the dielectric wafer to the functional wafer. Openings of the recesses and/or openings of the penetrations cover the photodetector elements. The penetrations form cavities together with a main surface of the functional wafer the cavities having bottom faces. The method additionally includes arranging optical filter elements in the recesses and/or in the cavities. The dielectric wafer is thinned prior to the arrangement of the optical filter elements.

A method for manufacturing a photodetector device and a photodetector device are provided.

An improved method for manufacturing a photodetector device, particularly with small dimensions, is to be provided. Further, a photodetector device having small dimensions is to be provided.

These objects are achieved with a method comprising the steps of claim 1 and a photodetector device having the features of claim 10.

Developments and embodiments of the method and the photodetector device are given in the respective dependent claims.

According to an embodiment of the method for manufacturing a photodetector device, a functional wafer with at least two photodetector elements, wherein the photodetector elements are configured to detect electromagnetic radiation of a first wavelength range during operation, is provided. Particularly, the functional wafer comprises more than two photodetector elements. For example, the functional wafer comprises a plurality of photodetector elements.

The functional wafer has a main extension plane, a first main surface and a second main surface opposite to the first main surface. The first main surface and the second main surface extend along the main extension plane, particularly. A thickness of the functional wafer is given by a distance between the first main surface and the second main surface.

According to a further embodiment of the method, a dielectric wafer transmissive for the electromagnetic radiation of the first wavelength range, is provided. Particularly, the dielectric wafer comprises at least two recesses and/or at least two penetrations. The penetrations penetrate the dielectric wafer from the first main surface to the second main surface. In particular, the recesses have bottom faces, while the penetrations penetrate the dielectric wafer completely. In other words, the penetrations are free of bottom faces and formed by sidewalls within the dielectric wafer, while the recesses do not penetrate the dielectric wafer completely. Therefore, the recesses have bottom faces. Particularly, the recesses and the penetrations extend from the first main surface and/or the second main surface perpendicular to the main extension plane in the dielectric wafer. For example, the dielectric wafer has a thickness between and including 200 micrometer and 300 micrometer.

Particularly, the dielectric wafer transmits at least 80% of electromagnetic radiation of the first wavelength range or at least 90% of electromagnetic radiation of the first wavelength range, not taking into account a reflectance of the electromagnetic radiation at the interface of the dielectric wafer to the surrounding medium, such as air. For example, the dielectric wafer comprises or consists of an oxide or a nitride, such as silicon oxide or silicon nitride. Particularly, the dielectric wafer comprises or consists of a glass.

Particularly, also the dielectric wafer has a main extension plane and a first main surface opposite to a second main surface. Particularly, the first main surface of the dielectric wafer and the second main surface of the dielectric wafer extend along the main extension plane of the dielectric wafer and are parallel to each other as well as to the main extension plane of the dielectric wafer. A thickness of the dielectric wafer is given by a distance between the first main surface and the second main surface of the dielectric wafer.

According to a further embodiment of the method, the dielectric wafer is connected to the functional wafer, wherein openings of the recesses and/or openings of the penetrations cover the photodetector elements. Further, the penetrations form cavities together with a main surface of the functional wafer. The cavities have bottom faces.

At present, the recesses already have bottom faces before connecting the dielectric wafer to the functional wafer. In contrast, the penetrations completely penetrate the dielectric wafer. The cavities having bottom faces are formed when the dielectric wafer with the penetrations is connected to the functional wafer. After connection of the dielectric wafer to the functional wafer, the cavities formed by the penetrations and a main surface of the functional wafer and the recesses have the same function. Further, the recesses and the cavities have openings arranged within a main surface of the dielectric wafer and bottom faces opposite to the openings. If not further specified in the following, openings and bottom faces designate openings and bottom faces of the cavities as well as of the recesses.

According to a further embodiment of the method, optical filter elements are arranged in the recesses and/or in the cavities. Particularly, the optical filter elements are arranged on the bottom surfaces. The optical filter elements are configured to transmit second wavelength ranges of the first wavelength range. Particularly, the second wavelength ranges transmitted by the optical filter elements consist of parts of the first wavelength ranges. The optical filter elements preferably block the parts of the first wavelength range not being transmitted. Preferably, the optical filter elements are interference filters.

Particularly, the optical filter elements fill the recesses and/or the cavities completely in a lateral direction extending along the main extension plane. In a vertical direction perpendicular to the lateral direction, the recesses and/or cavities are not completely filled by the optical filter elements, for example.

Particularly, the method for manufacturing the photodetector device comprises the steps:
providing the functional wafer with the at least two photodetector elements, the photodetector elements being configured to detect the electromagnetic radiation of the first wavelength range,
providing the dielectric wafer being transmissive for the electromagnetic radiation of the first wavelength range, the dielectric wafer comprising the at least two recesses and/or the at least two penetrations, the recesses having the bottom faces and the penetrations penetrate the dielectric wafer completely,
connecting the dielectric wafer to the functional wafer, wherein the openings of the recesses and/or the openings of the penetrations cover the photodetector elements and wherein the penetrations form the cavities together with the main surface of the functional wafer, the cavities having the bottom faces, and
arranging the optical filter elements in the recesses and/or in the cavities.

Particularly, the steps of the method are conducted in the given order.

It is an idea of the method to structure the dielectric wafer for introducing the optical filter elements instead of the functional wafer. Structuring of the dielectric wafer has the advantage that the recesses and/or penetrations for introducing the optical filter elements can be generated in the dielectric wafer with a smaller distance to each other than in the functional wafer. This simplifies the method for manufacturing the photodetector devices. Moreover, the optical filter elements can be arranged closer to each other in the lateral direction according to the present method such that photodetector devices with smaller dimensions can be provided.

Preferably, the method is carried out on wafer level. In other words, a plurality of photodetector devices is manufactured in parallel conducted process steps. If the method is carried out on wafer level, the functional wafer comprises a plurality of photodetector elements and the dielectric wafer comprises a plurality of recesses and/or penetrations. By connecting the dielectric wafer to the functional wafer, a wafer compound is achieved, which is further processed in order to form photodetector devices comprised by the wafer compound. At a later stage, the photodetector devices are separated from each other by singulation of the wafer compound along separation lines. In the following, features and embodiments may be described in terms of a singular photodetector device for the sake of clarity. However, these features and embodiments can be also embodied for more than one or a plurality of photodetector devices.

According to a further embodiment of the method, during the arrangement of the optical filter elements in the recesses and/or in the cavities, the opening of at least one recess and/or the opening of at least one cavity are covered with a mask layer leaving at least one opening free. If the method is carried out on wafer level, wherein a plurality of photodetector devices is manufactured, the opening of at least one recess and/or the opening of at least one cavity of each latter photodetector device is covered with the mask layer, for example, leaving at least one opening of at least one recess and/or the opening of at least one cavity of each latter photodetector device free. For example, a photoresist layer is used as the mask layer.

According to a further embodiment of the method, the optical filter element is deposited on the bottom face of the at least one recess and/or the at least one cavity having the free opening. In such a way, optical filter elements each having a specific spectral property are arranged in the recesses and/or in the cavities. Particularly, within the finished photodetector device an optical filter element together with the photodetector element covered by the optical filter element, forms an optical channel being configured to detect a specific spectral range of the first wavelength range.

According to a further embodiment of the method, arranging the optical filter elements in the recesses and/or in the cavities comprises:
covering the opening of the at least one recess and/or the opening of the at least one cavity with the mask layer leaving at least one opening free, and
depositing the optical filter element on the bottom face of the at least one recess and/or on the bottom face of the at least one cavity having the free opening.

Particularly, these method steps are repeated in order to provide different recesses and/or cavities with different optical elements having different optical properties. Thus, different optical channels of the finished photodetector devices can be achieved.

According to a further embodiment of the method, the optical filter elements comprise or consist of a plurality of single layers. For example, the single layers are dielectric layers comprising or consisting of an oxide or a nitride. For example, the optical filter elements comprise or consist of single layers alternatingly arranged above each other. For example, the single layers of the optical filter element are deposited by one of the following methods: chemical vapour deposition (CVD), plasma enhanced chemical vapour deposition (PECVD), physical vapour deposition (PVD), atomic layer deposition (ALD).

According to a further embodiment of the method, the recesses and/or the cavities are separated from each other by bars. In other words, the bars are arranged between the recesses and/or between the cavities. Particularly, the bars extend from the first main surface to the second main surface and are formed from the material of the dielectric wafer. Particularly, the side faces of the bars form side faces of the recesses and/or side faces of the cavities.

According to a further embodiment of the method, front faces of at least two bars are coated at least partially with material of the optical filter elements during deposition of the optical filter elements. Particularly, the mask layer does not completely cover the front faces of the bars, for example due to alignment tolerances. Therefore, material of the optical filter elements is deposited on the front faces of the bars during deposition.

According to a further embodiment of the method, the material of the optical filter elements is removed from the front faces of the bars, for example by grinding. It is also possible to remove the material of the optical filter element from the front faces of the bars by polishing or electrochemical polishing.

According to a further embodiment of the method, the dielectric wafer is thinned prior to the arrangement of the optical filter elements within the recesses and/or within the cavities. Preferably, the thinning takes place by grinding. It is further possible to thin the dielectric wafer by polishing or electrochemical polishing. Particularly, the dielectric wafer is thinned such that a depth of the cavities and/or of the recesses is at least twice as large as the thickness of the thickest optical filter element. This ensures that there is sufficient material of the dielectric wafer left for subsequent processing. Preferably, the dielectric wafer is thinned after connecting the dielectric wafer to the functional wafer.

According to a further embodiment of the method, cross-sectional areas of the cavities and/or of the recesses taper from the bottom faces to the openings. In other words, a cross-sectional area of the bottom face is larger than a cross-sectional area of the openings. Particularly, the side faces of the cavities and/or of the recesses are inclined with respect to a normal of the main extension plane of the dielectric wafer. If the cross-sectional areas of the openings are smaller than the cross-sectional areas of the bottom faces, deposition of material of the optical filter elements on the side faces of the recesses and/or of the cavities is avoided. For example, a diameter of the openings of the cavities and/or of the recesses is at least 10 micrometer. It is also possible, that the cross-sectional areas of the cavities and/or of the recesses taper from the openings to the bottom faces.

According to a further embodiment of the method, an absorbing layer is arranged on the bars separating the recesses and/or the cavities from each other. Particularly, the absorbing layer absorbs electromagnetic radiation of the first wavelength range detected by the photodetector elements during operation. For example, the absorbing layer is a dielectric layer, a further optical element, a metal layer or a polymer layer, the polymer layer being, for example, filled with carbon.

With the method described so far, a photodetector device can be manufactured. Therefore, features and embodiments disclosed in connection with the method can also be embodied within the photodetector device and vice versa.

According to an embodiment, the photodetector device comprises at least two photodetector elements configured for detecting electromagnetic radiation of a first wavelength range during operation. Particularly, the first wavelength range detected by the photodetector elements is a broad spectral range comprising, for example, visible light from the ultraviolet spectral to the infrared spectral range. Preferably, the photodetector elements are embodied equal to each other.

According to an embodiment, the photodetector device further comprises at least two optical filter elements covering the photodetector elements, the optical filter elements transmit second wavelength ranges of the first wavelength range. The second wavelength ranges are different from each other, preferably.

Particularly, the optical filter elements transmit different second wavelength ranges of the first wavelength range. In other words, each optical filter element filters a different part of the first wavelength range detected by the photodetector elements of the photodetector device. Particularly, an optical filter element transmits a first part of the first wavelength range and absorbs the other part of the first wavelength range. Preferably, each optical filter element transmits a different part of the first wavelength range. Each optical filter element and the photodetector element covered by the optical filter element are part of an optical channel of the photodetector device, wherein the optical channels of the photodetector device detect different spectral ranges.

According to a further embodiment of the photodetector device, the optical filter elements are arranged in depressions of a dielectric carrier connected to the photodetector elements. At present, the depressions described in connection with the photodetector device correspond to the recesses and/or cavities described in connection with the method for manufacturing the photodetector device. Features and embodiments disclosed at present in connection with the cavities and/or the recesses can therefore also be embodied in connection with the depressions and vice versa. Particularly, the depressions have openings and bottom faces as already described in connection with the cavities and/or recesses.

Further, the dielectric carrier is a part of the dielectric wafer, the dielectric carrier being generated by separating the wafer compound of the functional wafer and the dielectric wafer after processing the photodetector devices within the wafer compound. Features and embodiments disclosed at present in connection with the dielectric wafer can therefore also be embodied in connection with the dielectric carrier and vice versa. Particularly, the dielectric carrier is transmissive for the electromagnetic radiation of the first wavelength range.

According to an embodiment, the photodetector device comprises:
the at least two photodetector elements configured for detecting the electromagnetic radiation of the first wavelength range during operation,
the at least two optical filter elements covering the photodetector elements, the optical filter elements transmit the second wavelength ranges of the first wavelength range, wherein
the optical filter elements are arranged in the depressions of the dielectric carrier connected to the photodetector elements, and
the dielectric carrier is transmissive for the electromagnetic radiation of the first wavelength range.

According to a further embodiment of the photodetector device, the depressions have cross-sectional areas being, for example, constant from the bottom faces of the depressions to the openings of the depressions. It is also possible that the cross-sectional areas of the depressions taper from the bottom faces of the depression to the openings of the depressions. Particularly, depressions with cross-sectional areas being constant from bottom faces to the openings are provided with steep side faces allowing a very narrow arrangement of the optical filter elements arranged within the depressions, advantageously. Thus, a photodetector device with a compact design can be achieved.

According to a further embodiment of the photodetector device, side faces of the depression are at least partially formed by the material of the dielectric carrier.

According to a further embodiment of the photodetector device, a distance between the side faces of two directly adjacent depressions is at most 50 micrometer, at most 30 micrometer, at most 10 micrometer or at most 5 micrometer.

According to a further embodiment of the photodetector device, an absorbing layer is arranged on front faces of bars separating the depressions from each other. Particularly, one bar is arranged between two directly adjacent depressions and covered on the front face with the absorbing layer, preferably completely. It is also possible that the absorbing layer extends the front faces of the bars in a lateral direction. Particularly, the absorbing layer absorbs electromagnetic radiation of the first wavelength range. This leads to an enhanced contrast of the optical channels of the photodetector device.

According to a further embodiment of the photodetector device, the photodetector elements are photodiodes. For example, the photodiodes comprise or consist of pn-junctions within a semiconductor layer. For example, the semiconductor layer is p-doped or n-doped and comprises oppositely doped regions in order to form the pn-junctions. For example, the semiconductor layer comprises or consists of p-doped or n-doped silicon.

The photodetector device can, for example, find application in optical sensors, optical transceivers, display management devices, biosensors, proximity sensors, spectrometers.

Further advantageous embodiments and developments of the method for manufacturing a photodetector device and the photodetector device result from the exemplary embodiment described below in connection with the Figures.

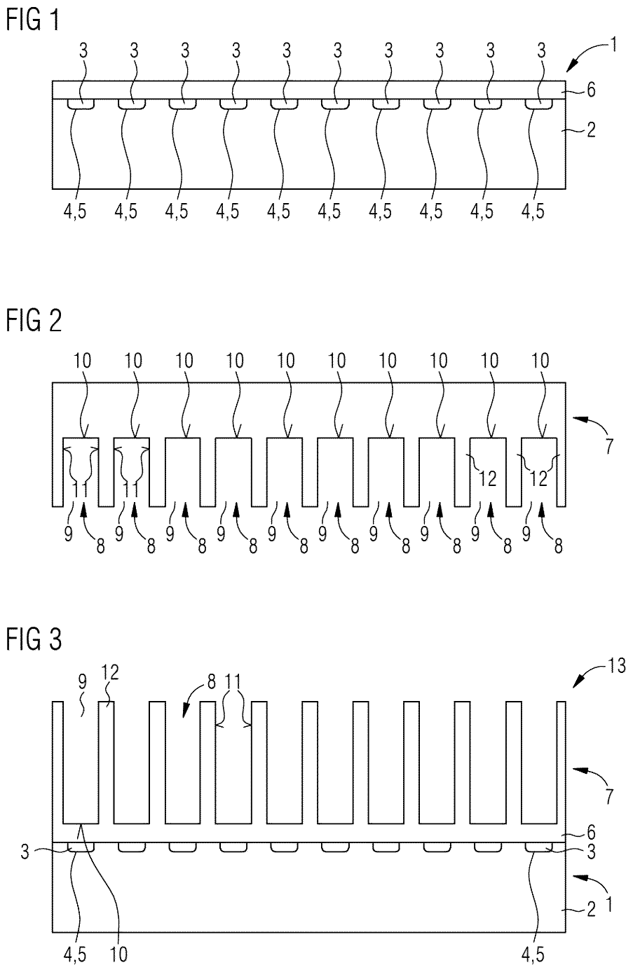

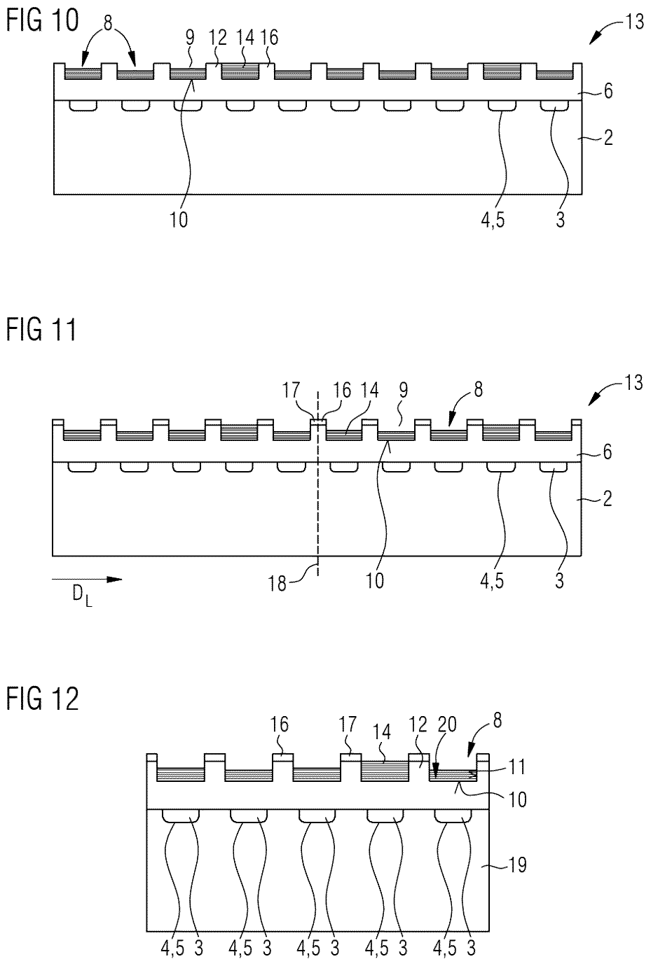

FIGS. 1 to 11 show schematic sectional views of stages of a method for manufacturing a photodetector device according to an exemplary embodiment.

FIG. 12 shows a schematic sectional view of a photodetector device according to an exemplary embodiment.

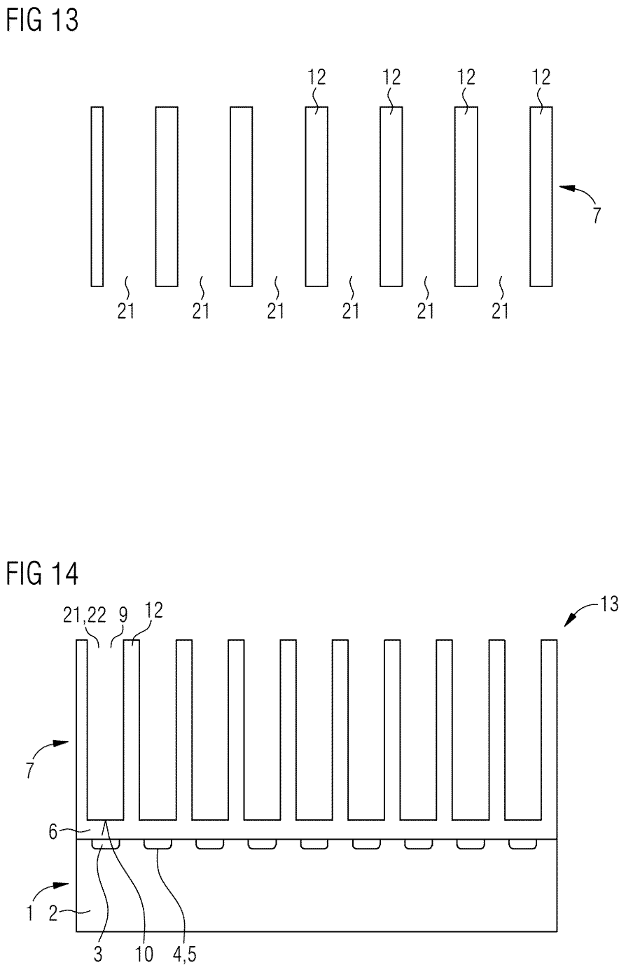

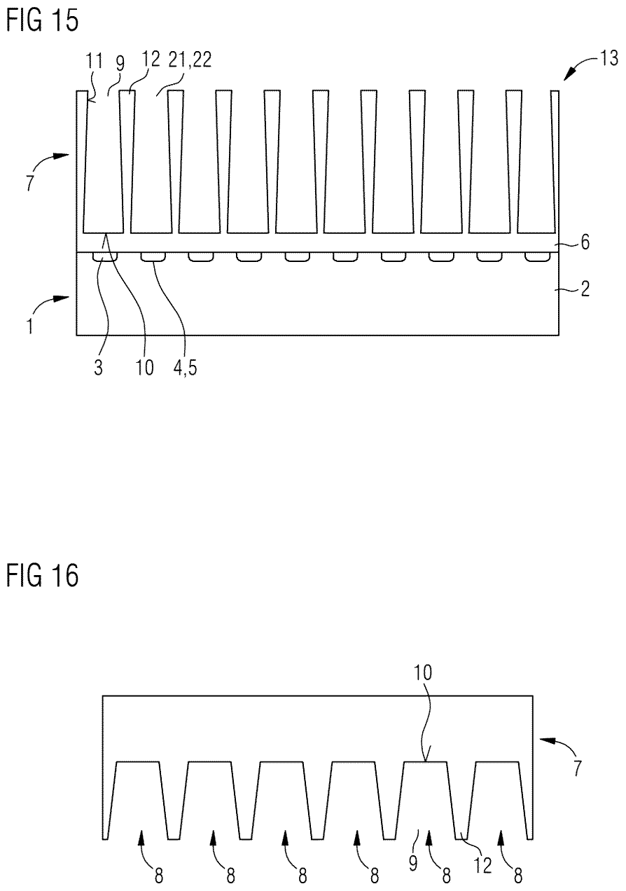

FIGS. 13 and 14 show schematic sectional views of stages of a method for manufacturing a photodetector device according to a further exemplary embodiment.

FIGS. 15 and 16 show schematic sectional views of stages of a method for manufacturing a photodetector device according to two further exemplary embodiments.

Equal or similar elements as well as elements of equal function are designated with the same reference signs in the Figures. The Figures and the proportions of the elements shown in the Figures are not regarded as being shown to scale. Rather, single elements, in particular layers, can be shown exaggerated in magnitude for the sake of better presentation and/or better understanding.

During the method according to the exemplary embodiment of FIGS. 1 to 11, a functional wafer 1 is provided (FIG. 1). The functional wafer 1 comprises semiconductor layer 2. The semiconductor layer comprises p-doped silicon. In the semiconductor layer 2 n-doped regions 3 are inserted from a first main surface of semiconductor layer 2. The n-doped regions 3 form trough-like volumes within the p-doped silicon layer. At an interface of the n-doped regions and the p-doped semiconductor layer 2 pn-junctions 4 are generated. The pn-junctions 4 are part of photodetector elements 5 detecting electromagnetic radiation of a first wavelength range during operation.

On the first main surface of the semiconductor layer 2, a dielectric layer 6 is arranged covering the photodetector elements 5. The dielectric layer 6 comprises, for example, an oxide or a nitride, such as silicon oxide or silicon nitride. Within the dielectric layer 6, metal structures are embedded (not shown). The metal structures form electrical connections of the photodetector elements 5 within the finished photodetector devices.

Further, a dielectric wafer 7 is provided as, for example, shown in FIG. 2. The dielectric wafer 7 comprises a plurality of equally formed recesses 8 extending from a first main surface of the dielectric wafer 7 to a second main surface of the dielectric wafer 7. The recesses 8 have openings 9 at the first main surface and bottom faces 10 arranged opposite to the openings 9. The bottom faces 10 and the openings 9 are connected to each other by side faces 11 of the recesses 8.

The dielectric wafer 7 comprises or consists of silicon oxide or silicon nitride, for example. Particularly, the dielectric wafer 7 comprises or consists of the same dielectric material as the dielectric layer 6.

The side faces 11 of the recesses 8 extend perpendicular to a main extension plane of the dielectric wafer 7. In other words, the side faces 11 are not intentionally inclined according to the exemplary embodiment. For example, the recesses 8 are etched, for example with plasma enhanced chemical etching, within the dielectric wafer 7. A diameter of the openings 9 is mainly determined by an etching aspect ratio. For example, the etching aspect ratio lies between and including 1:10 and 1:20. A minimum thickness of the dielectric wafer 7 is, for example, between and including 200 micrometer and 300 micrometer. Therefore, a minimum diameter of the openings 9 of about 10 micrometer is possible. For example, a diameter of the bottom faces 10 is equal to a diameter of the openings 9.

Bars 12 are arranged between the recesses 8, separating two directly adjacent recesses 8 from each other. The bars 12 are formed from the dielectric material of the dielectric wafer 7.

At present, the manufacturing of two photodetector devices is shown exemplarily in the Figures. However, the functional wafer 1 and the dielectric wafer 7 comprise a plurality of recesses 8 and a plurality of photodetector elements 5 in order to produce a plurality of photodetector devices on wafer level in parallel process steps.

The dielectric wafer 7 is connected to the functional wafer 1 by fusion bonding under the impact of heat and pressure (FIG. 3). Particularly, the dielectric wafer 7 is attached with the second main surface to the first main surface of the functional wafer 1 such that a wafer compound 13 is achieved.

Within the wafer compound 13, the openings 9 of the recesses 8 cover the photodetector elements 5. In other words, seen in plan view on the wafer compound 13, the photodetector elements 5 are arranged within the openings 9.

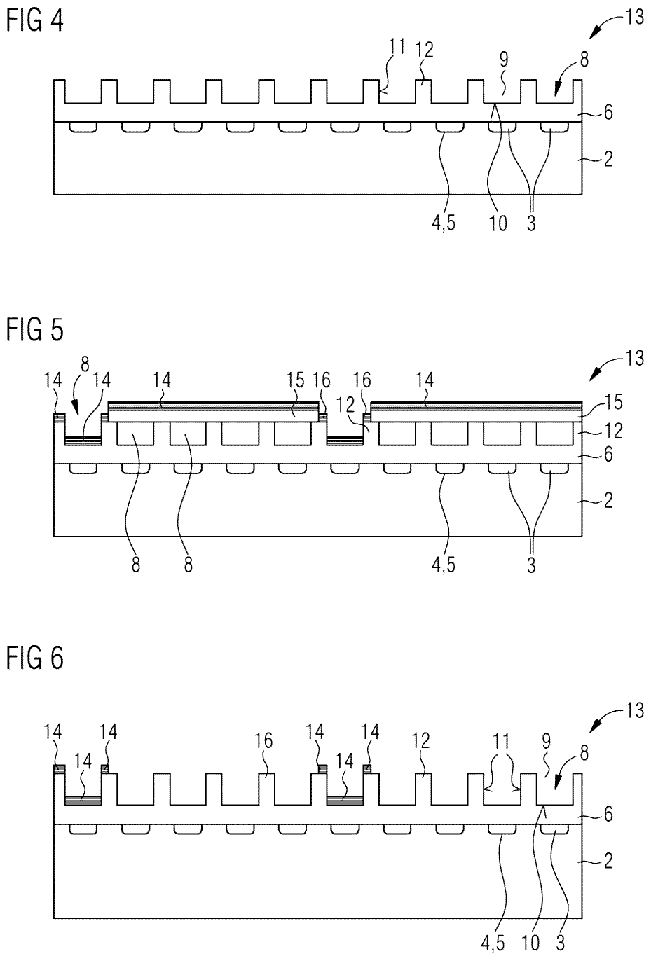

After connection to the functional wafer 1, the dielectric wafer 7 is thinned, for example by grinding (FIG. 4). Particularly, after thinning a depth of the recesses 8 is at least twice as large as the greatest thickness of optical filter elements 14 to be deposited within the recesses 8 in the following steps.

The recesses 8 which are not intended to be subsequently filled with an optical filter element 14 are covered by a mask layer 15, while at least one recess 8 is free of the mask layer 15 (FIG. 5). At present, one recess 8 of each photodetector device to be manufactured is not covered by the mask layer 15. For example, the mask layer 15 is a photoresist layer.

Then, a layer sequence of single layers of an optical filter element 14 is deposited on the wafer compound 13, for example by CVD, PECVD, PVD or ALD.

At present, the mask layer 15 does not completely cover the bars 12 directly adjacent to the recess 8 to be provided with the optical filter element 14 due to manufacturing tolerances. Therefore, material of the optical filter elements 14 is not only deposited within the recesses 8 to be provided with the optical filter elements 14 but are also at least partially on front faces 16 of the bars 12 after removing the mask layer 15 (FIG. 6).

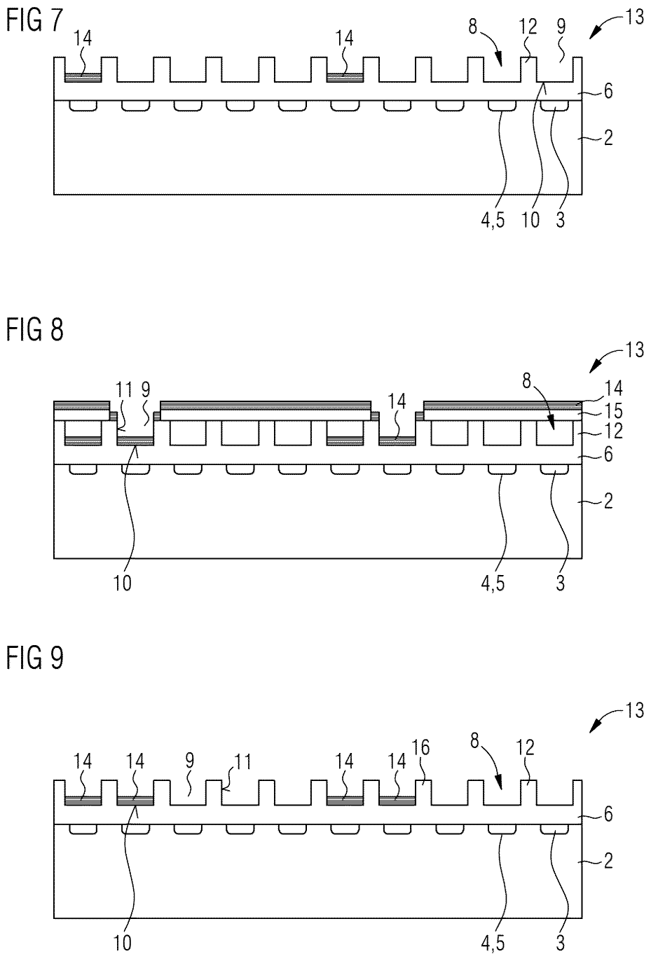

After removing the mask layer 15, the material of the optical filter elements 14 on the front faces 16 of the bars 12 is removed, for example by grinding (FIG. 7).

Then, the steps as already explained in connection with FIGS. 5, 6 and 7 are repeated, wherein different recesses 8 are not covered by the mask layer 15 and freely accessible for deposition of optical filter elements 14 (FIG. 8). Particularly, again a mask layer 15 is deposited that preferably covers all recesses 8 of a later photodetector device, leaving one recess 8 of each photodetector device to be manufactured freely accessible. Then, further optical filter elements 14 are arranged at the bottom faces 10 of the freely accessible recesses 8. The optical filter elements 14 deposited in this step are particularly different from the optical filter elements 14 deposited previously as described in connection with FIGS. 5, 6 and 7.

Again, the mask layer 15 is removed and the material of the optical filter elements 14 deposited on the bars 12 directly adjacent to the recesses 8 being provided with the optical filter elements 14 in the step of FIG. 8 is removed, for example again by grinding (FIG. 9).

The steps described in connection with FIGS. 5, 6 and 7 are repeated until all recesses 8 are provided at their bottom faces 10 with optical filter elements 14 being different from each other within one finished photodetector device. The optical filter elements 14 of each finished photodetector device have different single layers in order to realise different optical filtering functions. Therefore, some recesses 8 are filled to a greater extend in a vertical direction by the optical filter elements 14 than others.

The front faces 16 of the bars 12 between the recesses 8 are covered with an absorbing layer 17, preferably completely (FIG. 11). It is also possible that the absorbing layer 17 extends partially in a lateral direction D_{L} over the adjacent optical filter element 14. The absorbing layer 17 particularly absorbs electromagnetic radiation of the first wavelength range.

The wafer compound 13 with the finished photodetector devices is separated along separation lines 18 into single photodetector devices.

The photodetector device according to the exemplary embodiment of FIG. 12 is, for example, manufactured with the method described in connection with FIGS. 1 to 11.

The photodetector device according to the exemplary embodiment of FIG. 12 comprises several photodetector elements 5 arranged laterally to each other within a semiconductor layer 2 being a p-doped silicon layer at present. Within the semiconductor layer 2 n-doped trough-shaped regions 3 are arranged. The interfaces between the n-doped trough-shaped regions 3 and the p-doped semiconductor layer 2 form pn-junctions 4 as functional parts of the photodetector elements 5 detecting electromagnetic radiation.

On the semiconductor layer 2 a dielectric layer 6 is applied. The dielectric layer 6 comprises metallic structures for electrical contact and control of the photodetector elements 5. The metallic structures are not shown in the Figure.

The photodetector device of the exemplary embodiment of FIG. 12 further comprises a dielectric carrier 19 having depressions 20. The depressions 20 cover the photodetector elements 5 seen in plan view. The depressions 20 have bottom faces 10 and openings 9 arranged opposite to the bottom faces 10. Side faces 11 of the depressions 20 connect the bottom faces 10 and the openings 9.

An optical filter element 14 is arranged within each depression 20 in direct contact with the bottom face 10 and the side faces 11. The depressions 20 are separated from each other by bars 12, also formed of material of the dielectric carrier 19. Front faces 16 of the bars 12 are completely covered with an absorbing layer 17.

The photodetector elements 5 are configured for detecting electromagnetic radiation of a first wavelength range. The optical filter elements 14 within the depressions 20 transmit second wavelength ranges, the second wavelength ranges transmitted by the optical filter elements 14 being different from each other. Each optical filter element 14 transmits a different part of the first wavelength range and absorbs a further part of the first wavelength range. The optical filter element 14 together with the underlying photodetector element 5 form an optical channel for detection of a specific part of the first wavelength range.

In the method according to the exemplary embodiment of FIGS. 13 and 14, again a functional wafer 1 is provided as, for example, already described in connection with FIG. 1.

Further, a dielectric wafer 7 is provided (FIG. 13). In contrast to the dielectric wafer 7 described in connection with FIG. 2, the dielectric wafer 7 provided in the method according to the exemplary embodiment of FIGS. 13 to 14 comprises penetrations 21 penetrating the dielectric wafer 7 completely from a first main surface to an opposite second main surface. In other words, the dielectric wafer 7 does not comprise recesses 8 having bottom faces 10 but penetrations 21. The penetrations 21 are separated from each other by bars 12.

The dielectric wafer 7 is connected to the functional wafer 1 with the photodetector elements 5 such that openings 9 of the penetrations 21 cover the photodetector elements 5 (FIG. 14). The dielectric wafer 7 is connected in a mechanically stable manner to the functional wafer 1 such that a wafer compound 13 is formed. After connection of a dielectric wafer 7 and the functional wafer 1, the penetrations 21 form cavities 22 together with a first main surface of the functional wafer 1. Particularly, parts of the first main surface of the functional wafer 1 forms bottom faces 10 of the cavities 22.

After connecting the functional wafer 1 and the dielectric wafer 7 mechanically stable to each other, for example by fusion bonding, the method steps are carried out as, for example, already described in connection with FIG. 4 to FIG. 11.

FIG. 15 shows a stage of a method according to a further exemplary embodiment. Compared to the method of the exemplary embodiment of FIGS. 13 to 14, the dielectric wafer 7 that is to be connected to the functional wafer 1 to form a wafer compound 13 comprises penetrations 22 with inclined side faces 11. After connecting the dielectric wafer 7 to the functional wafer 1, the penetrations 21 form cavities 22 together with a first main surface of the functional wafer 1. The cavities 22 have cross-sectional areas decreasing from bottom faces 10 of the cavities 22 to bottom faces 10 of the cavities 22.

As, for example, shown in FIG. 16, it is also possible to provide a dielectric wafer 7 with recesses 8 having side faces 11. Cross-sectional areas of the recesses 8 of the dielectric wafer 7 shown in FIG. 16 taper from openings 9 of the recesses 8 to bottom faces 10 of the recesses 8.

This application claims priority of the German application DE 102023113587.2, the disclosure content of which is incorporated by reference.

The invention is not limited to the description of the exemplary embodiments. Rather, the invention comprises each new feature as well as each combination of features, particularly each combination of features of the claims, even if the feature or the combination of features itself is not explicitly given in the claims or the exemplary embodiments.

### REFERENCES

1 functional wafer
2 semiconductor layer
3 region
4 pn-junction
5 photodetector element
6 dielectric layer
7 dielectric wafer
8 recess
9 opening
10 bottom face
11 side face
12 bar
13 wafer compound
14 optical filter element
15 mask layer
16 front face
17 absorbing layer
18 separation line
19 dielectric carrier
20 depression
21 penetration
22 cavity
D_{L} lateral direction

1. A method for manufacturing a photodetector device, comprising the steps:
providing a functional wafer with at least two photodetector elements, the photodetector elements being configured to detect electromagnetic radiation of a first wavelength range,
providing a dielectric wafer being transmissive for the electromagnetic radiation of the first wavelength range, the dielectric wafer comprising at least two recesses and/or at least two penetrations, the recesses having bottom faces and the penetrations penetrate the dielectric wafer completely,
connecting the dielectric wafer to the functional wafer, wherein openings of the recesses and/or openings of the penetrations cover the photodetector elements and wherein the penetrations form cavities together with a main surface of the functional wafer, the cavities having bottom faces, and
arranging optical filter elements in the recesses and/or in the cavities,
wherein
the dielectric wafer is thinned prior to the arrangement of the optical filter elements.

2. The method according to claim 1, wherein arranging the optical filter elements in the recesses and/or in the cavities comprises:
covering the opening of at least one recess and/or the opening of at least one cavity with a mask layer leaving at least one opening free, and
depositing the optical filter element on the bottom face of the at least one recess and/or on the bottom face of the at least one cavity having the free opening.

3. The method according to claim 1, wherein
the optical filter elements comprise a plurality of single layers.

4. The method according to claim 1, wherein
the recesses and/or the cavities are separated from each other by bars,
front faces of at least two bars are coated at least partially with material of the optical filter elements during depositing the optical filter elements, and
the material of the optical filter elements is removed from the front faces of the bars by grinding.

5. (canceled)

6. The method according to claim 1, wherein a remaining depth of the cavities and/or of the recesses after thinning is at least twice as large as the thickness of the thickest optical filter element.

7. The method according to claim 1, wherein
cross-sectional areas of the cavities and/or of the recesses taper from the bottom faces to the openings.

8. The method according to claim 1, wherein
a diameter of the openings of the penetrations and/or the cavities and/or the recesses is at least 10 micrometer.

9. The method according to claim 1, wherein
an absorbing layer is arranged on the bars separating the recesses and/or the cavities from each other.

10. A photodetector device, comprising:
at least two photodetector elements configured for detecting electromagnetic radiation of a first wavelength range during operation,
at least two optical filter elements covering the photodetector elements, the optical filter elements transmit second wavelength ranges of the first wavelength range,
wherein
the optical filter elements are arranged in depressions of a dielectric carrier connected to the photodetector elements,
the dielectric carrier is transmissive for the electromagnetic radiation of the first wavelength range, and
an absorbing layer is arranged on front faces of bars separating the depressions,
the depressions have cross-sectional areas, the cross-sectional areas taper to the openings of the depressions.

11. (canceled)

12. The photodetector device according to claim 9, wherein
side faces of the depressions are at least partially formed by material of the dielectric carrier.

13. The photodetector device according to claim 9, wherein
a distance between the side faces of two adjacent depressions is at most 15 micrometer.

14. The photodetector device according to claim 9, wherein
the photodetector elements are photodiodes.
